(19) United States
(12) Patent Application Publication
(10) Pub. No.: US 2006/0211257 A1
(43) Pub. Date: Sep. 21, 2006

(54) Compound, semiconductor component, and method for producing a semiconductor component comprising an organic memory material

(76) Inventors: Marcus Halik, Erlangen (DE); Hagen Klauk, Stuttgart (DE); Guenter Schmid, Hemhofen (DE); Ute Zschieschang, Stuttgart (DE)

Correspondence Address: SLATER & MATSIL LLP, 17950 PRESTON ROAD, SUITE 1000, DALLAS, TX, 75252, US

(21) Appl. No.: 11/364,134

(22) Filed: Feb. 28, 2006

Related U.S. Application Data
(63) Continuation of application No. PCT/DE04/01936, filed on Aug. 27, 2004.

(30) Foreign Application Priority Data
Aug. 29, 2003 (DE) 103 40 610.7

(51) Int. Cl. H01L 21/302; H01L 21/461

(52) U.S. Cl. 438/754

(57) ABSTRACT

The invention relates to a compound comprising at least one memory unit consisting of an organic memory material, especially for use in CMOS structures, said compound being characterized by a) at least one first anchor group (1) provided with a reactive group for covalently bonding to a first electrode (10), especially a bottom electrode of a memory cell (102), and b) at least one second anchor group (2) provided with a reactive group for bonding to a second electrode (20), especially a top electrode of a memory cell (102). The invention also relates to a semiconductor component, and to a method for producing a semiconductor component. The invention thus provides a compound, a semiconductor component, and a method for producing the semiconductor component, by which means molecular memory layers can be efficiently formed on conventional substrates.

This application is a continuation of co-pending International Application No. PCT/DE2004/001936, filed Aug. 27, 2004, which designated the United States and was not published in English, and which is based on German Application No. 103 40 610.7 filed Aug. 29, 2003, both of which applications are incorporated herein by reference.

### TECHNICAL FIELD

The invention relates to a compound, a semiconductor component, and a method for producing a semiconductor component comprising an organic memory material.

### BACKGROUND

Organic molecules as memory units are increasingly being discussed for the purpose of increasing the storage density in semiconductor components. The memory cell of a semiconductor component could ideally be reduced to orders of magnitude in the molecular range (size depending on type of molecule, approximately 0.5 to 5 nm). In general, in order to increase the statistical confidence, a number of individual molecules limited by the electrode area (e.g., 10 nm×10 mn) (e.g., 100 molecules per memory cell, 1 nm² per molecule, 100 nm² per memory cell) is initially conceived for the production of a memory function.

The literature has previously described a series of potentially suitable molecular backbones and demonstrated first memory effects (C. P. Collier, E. W. Wong, M. Belohradsky, F. M. Raymo, J. F. Stoddart, P. J. Kuekes, R. S. Williams, J. R. Heath, “Electronically Configurable Molecular Based Logic Gates,” Science 285 (1999) 391; D. I. Gittins, D. Bethell, D. J. Schifflin, R. J. Nichols, “A nanometre-scale electronic switch consisting of a metal cluster and redox addressable groups,” Nature 408 (2000) 67; Z. J. Donhauser, B. A. Mantooth, K. F. Kelly, L. A. Bumm, J. D. Monnell, J. J. Stapleton, D. W. Price Jr., A. M. Rawlett, D. L. Allara, J. M. Tour, P. S. Weiss, “Conductance Switching in Single Molecules Through Conformational Changes,” Science 292 (2001) 2303).

Collier, et al. describe a write-once memory cell that is based on the material class of the rotaxanes in conjunction with a bispyridinium unit. In order to examine the switching behavior on individual molecules, scanning tunneling microscopy (STM) is increasingly being used (see Gittins, et al. and Donhauser, et al.). Gittins, et al. describe the switching behavior of a bispyrdinium compound on a gold nanoparticle. Donhauser, et al. describe the switching behavior of phenylene-ethynylene oligomers by isolation with alkanethiolates.

In order to be able to realize the enormous potential of these molecular memory units (memory devices with terabyte capacity per square centimeter), it is necessary to provide a suitable infrastructure (that is to say electronics for reading, writing and erasing each individual cell) for such memory arrangements.

At the present time, generally only silicon CMOS technology is able to process such enormous quantities of data on small areas. Therefore, it is desired to integrate the organic memory molecules into silicon CMOS technology in a suitable manner.

The molecules discussed in the literature do not afford efficient solutions for integrating organic memory molecules into/onto existing CMOS platforms. Virtually all the molecular structures described preferably involve one or more thiol anchor group(s) (—SH) with or without linkers for fixing the molecule on the electrode surface. Therefore, gold is always used as the electrode material. However, the thiol anchor group/gold electrode system is unsuitable for integration (and particularly for integration with silicon CMOS) for various reasons.

As described in the literature cited above, a series of “memory-active” molecules exists.

The molecular memory media described heretofore have preferably been examined on gold electrodes, resulting from the great experience that exists in the case of depositing monolayers on gold (see Y. Xia, G. M. Whitesides, Angew. Chem. 1998, 568 to 594). In this case, the molecular monolayers are fixed on the gold surface by means of a thiol group (—SH). Since the gold/thiol system does not involve covalent binding of the thiol/thiolate with the gold atoms, rather the self-assembly effect of the monolayer is principally based on the lowering of the configuration entropy, this system is stable only to a limited extent.

Thus, self-assembling monolayers (SAMs) with thiol anchor groups on gold surfaces are not stable for example with respect to the action of various organic and inorganic solvents. Furthermore, related to processability and long-term stability, the SAMs are thermostable with regard to diffusion only to a limited extent. That is to say that the molecules migrate or desorb (since they are not bound covalently) at elevated temperatures above room temperature on the gold surface and thus alter their properties (C. D. Bain, et al., J. Am. Chem. Soc., 1989, 111, 321 to 335). This also explains why Thiol SAMs often have to be deposited at temperatures below room temperature if a particularly high degree of tightness and homogeneity is required. However, even thiol SAMs deposited at temperatures below room temperature are not bound covalently and, accordingly, are still very unstable. This thermal instability of thiol-based SAMs is unacceptable for a product application, and, therefore, the gold/thiol system for the fixing of the molecules on the bottom electrode is undesirable.

Furthermore, the use of gold as electrode material for the bottom electrode is problematic in silicon CMOS processes since gold in close contact with the semiconductor silicon is a dangerous dopant. The use of gold for the bottom electrode is undesirable, therefore, from a process engineering standpoint.

The use of gold as material for the top electrode is somewhat less problematic since this use occurs distinctly later in the process; nevertheless, metals such as aluminum or copper are preferred here.

A symmetrical molecular design with two identical anchor groups, as described in Gittins, et al., is furthermore problematic. A symmetrical molecular design increases the probability of the molecules not being arranged as a closed monolayer (perpendicular or slightly angled with respect to the metal), but rather having a high concentration of defects attributable to the simultaneous “binding” at the anchor groups (and hence to a parallel arrangement of the molecules with respect to the gold substrate). This defective arrangement is based on the driving force of the anchor group to orient itself toward the metal.

To summarize, the disadvantages of the gold/thiol system for molecular memories are: (1) gold is required as bottom electrode, which is unfavorable for silicon CMOS technology, (2) thermally and chemically unstable arrangement of the memory molecule on the gold surface (low stability of the memory device and short service life), and (3) identical anchor groups at both ends of the molecules (symmetrical molecular design) lead to higher defect probability.

### SUMMARY OF THE INVENTION

In one aspect, the present invention provides a compound, a semiconductor component and a method for producing the semiconductor component by means of which it is possible efficiently to realize molecular memory layers on conventional substrates. A preferred embodiment of this invention is a targeted modification of molecules, specifically in the area of the anchor groups and linkers, which permits integration with silicon CMOS platforms.

This may be achieved with a compound having at least one first anchor group comprising a reactive group for covalent binding to a first electrode, in particular a bottom electrode of a memory cell, and at least one second anchor group comprising a reactive group for binding to a second electrode, in particular a top electrode of a memory cell.

In particular, the anchor groups make it possible to use organic molecular memory materials for integration on silicon-based circuits. It is thus possible to effect the integration in a simple manner on silicon substrates, generally with exclusive use of standard CMOS materials for the bottom electrodes (e.g., silicon, aluminum, titanium, copper), with targeted avoidance of silicon-CMOS-incompatible materials (e.g., gold). By virtue of the specific covalent binding of the organic memory units to the electrode materials via an anchor group, the memory cells according to preferred embodiments of the invention are distinctly stabler (with regard to temperature, chemicals and service life) in comparison with non-covalently bound compounds (e.g., thiol-based compounds). Consequently, the compound has a memory unit that is provided at its ends with anchor groups that are chosen selectively for specific electrode materials.

In one advantageous refinement of the compound according to embodiments of the invention, the first anchor group and the second anchor group are formed such that they are chemically different. It is thus possible for the compound to be automatically orientated to the electrodes used.

The compound advantageously has at least one of the following reactive groups: —SiCl₃, —SiCl₂-alkyl, —SiCl(alkyl)₂, —Si(OR)₃, —Si(OR)₂alkyl and/or —SiOR(alkyl)₂ for binding to a first electrode with silicon and a native silicon oxide layer, or silicon oxide layer produced in a targeted manner, with a hydroxy-terminated silicon Si—OH.

It is likewise advantageous if at least one of the following reactive groups: —CHO and/or —CH═CH₂ for photoinduced binding to a first electrode with silicon and a hydrogen-containing surface is present.

It is furthermore advantageous if at least one of the following reactive groups: —Li and/or —MgX (X: halogen) for binding to a first electrode with silicon and a halogen-containing surface is present.

A further advantageous refinement has at least one of the following reactive groups: —SiCl₃, —SiCl₂-alkyl, SiCl(alkyl)₂, —Si(OR)₃, —Si(OR)₂alkyl and/or —SiOR(alkyl)₂ for binding to a first electrode with titanium or aluminum with a native oxide layer, or oxide layer produced in a targeted manner, with a hydroxyl-terminated aluminum or titanium.

It is particularly advantageous if at least one first anchor group has a halosilane group and/or an alkoxysilene group.

The second anchor group advantageously has at least one —SH group, one —SO₂H group and/or one —PR₃ group for binding to a second electrode made of gold, at least one —NR2 group and/or —SH group for binding to a second electrode made of copper, at least one —NC group for binding to a second electrode made of platinum, at least one —PO₃H₂ group for binding to a second electrode (20) made of indium tin oxide (ITO) and/or at least one —COOH group and/or one —CONHOH group for binding to a second electrode (20) made of AI(AlOₓ).

In one advantageous embodiment, the memory unit has a linear molecular group, a conjugated phenylene-ethynylene oligomer and/or a compound comprising a bispyridyl group.

In one advantageous refinement of the compound according to embodiments of the invention, at least one anchor group is connected to a molecular memory unit via a linker, it being advantageous if at least one linker is an n-alkane or an aryl. Particular electrical effects can be obtained if the linkers are formed differently, in particular have different lengths.

Another preferred embodiment is a semiconductor component having at least one self-assembling monolayer comprising a compound as described herein above, the self-assembling monolayer being arranged between at least one first electrode and one second electrode. CMOS silicon platforms can thus be used efficiently.

It is advantageous if a first electrode, in particular a bottom electrode, comprises silicon, titanium, aluminum, titanium and/or copper. It is also advantageous if at least one second electrode, in particular a top electrode, comprises aluminum, titanium, gold, copper, platinum, ITO, TiNₓ, TaNₓ, WNₓ or Al(AlOₓ).

Another preferred embodiment is a method of applying the compounds to a substrate using a vapor phase deposition or a liquid phase deposition.

The vapor phase deposition is advantageously effected at a pressure of 10⁻⁶ to 400 mbar, a temperature of 80 to 300° C. and/or under a protective gas atmosphere.

The organic memory molecules are preferably deposited from the vapor phase, but may also be deposited from solution. In this case, the molecules are covalently bound to an Si/SiO₂ surface (bottom electrode) selectively by means of a suitable anchor group. The consequence of this covalent binding is that the organic memory molecules are bound very stably with regard to temperature, chemicals and diffusion, which distinctly improves subsequent processes (deposition and patterning of the top electrode) and also durability of the memory matrix.

The liquid phase deposition is advantageously effected from a slightly polar, aprotic solvent, in particular toluene, tetrahydrofuran, cyclohexane, having a concentration of 10⁻⁴ to 1%.

A first advantageous embodiment for producing semiconductor components comprises applying at least one first electrode for driving at least one memory cell on the substrate, then applying a sheetlike self-assembling monolayer comprising compounds described herein for the purpose of forming at least one memory cell, subsequently applying an etching mask and using it to perform a subtractive patterning of memory cells on the substrate, removing the etching mask, and then connecting at least one second electrode to at least one memory cell.

As an alternative, a second embodiment comprises applying at least one first electrode for driving a memory cell on the substrate, then applying a passivation layer, which is then provided with holes, subsequently applying the holes with a self-assembling monolayer comprising a compound described herein for the purpose of forming memory cells, and subsequently connecting at least one second electrode to at least one memory cell.

It is advantageous if an oxide layer, in particular an SiO₂ layer, is produced on the substrate by thermal oxidation, in particular in an oxidation furnace or rapid thermal processing, and/or a short action of an oxygen plasma.

### BRIEF DESCRIPTION OF THE DRAWINGS

The invention is explained in more detail below using a plurality of exemplary embodiments with reference to the figures of the drawings, in which:

FIG. 1 shows a schematic perspective view of a monomolecular memory layer of a semiconductor component between a bottom electrode and a top electrode;

FIG. 2a shows a schematic construction of an embodiment of the compound according to the invention;

FIG. 2b shows a schematic illustration of an embodiment of the compound according to the invention in connection with bottom and top electrodes;

FIGS. 3a-d show a first embodiment of a method for patterning a memory layer using an embodiment of the compound according to the invention; and

FIGS. 4a-d show a second embodiment of a method for patterning a memory layer using an embodiment of the compound according to the invention.

The following list of reference symbols can be used in conjunction with the figures:
1 First anchor group
2 Second anchor group
3 Memory Unit
4 First linker
5 Second linker
10 First electrode (bottom electrode)
20 Second electrode (top electrode)
100 Substrate
101 Self-assembling monolayer (memory SAM)
102 Memory cell
109 Passivation layer
103 Contact holes

### DETAILED DESCRIPTION OF ILLUSTRATIVE EMBODIMENTS

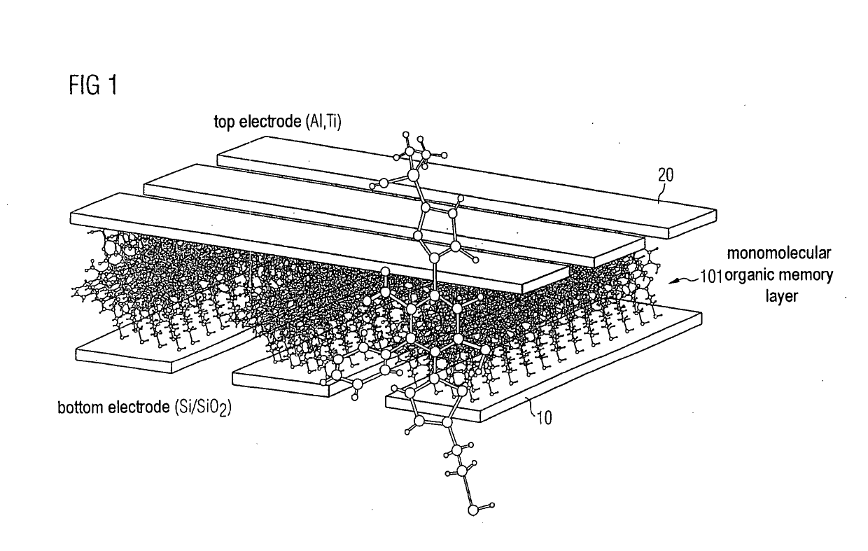

Preferred embodiments of the invention relate, inter alia, to compounds, which are suitable especially for stable integration in silicon CMOS platforms in order subsequently to produce therefrom a memory matrix with an underlying control unit based on silicon CMOS technology. Such a memory matrix (without control electronics) is illustrated schematically in FIG. 1. A self-assembling monolayer 101 comprising a memory unit is arranged between a top electrode 20 and a bottom electrode 10. The substrate on which the electrodes 10, 20 and the monolayer 101 are arranged is not illustrated in FIG. 1.

Firstly, the construction of the compounds, which are arranged in the self-assembling monolayer 101 or form the latter is discussed below.

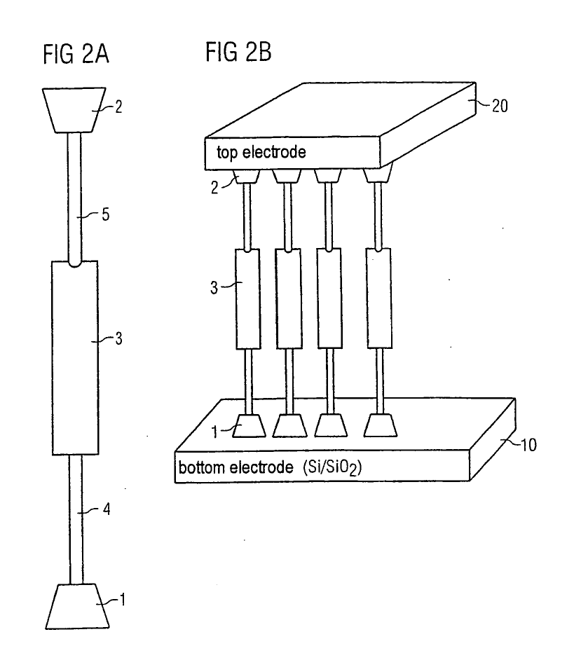

An embodiment of the compound according to the invention, which is illustrated schematically in FIGS. 2a and 2b generally, has three components:

1. An anchor group 1 for binding the compound to a first electrode 10 (here the bottom electrode). Anchor group 1 comprises, e.g., a reactive silicon group (halosilane, alkoxysilene), which binds selectively covalently to first electrode 10 (e.g., silicon with a native oxide layer a few nanometers thick).

2. A memory unit 3, which can be formed depending on the memory effect that can be utilized.

3. A second anchor group 2 for binding to a second electrode 20 (here the top electrode). This anchor group comprises corresponding reactive groups depending on the electrode material used:

| Electrode Material | Reactive Group |
|---|---|
| Au | —SH, —SO₂H, —PR₃ |
| Cu | —NR₂, —SH |
| Pt | —NC |
| ITO (Indium Tin Oxide) | —PO₃H₂ |
| Al (AlOₓ) | —COOH, —CONHOH etc. |
| TaNₓ, TiNₓ WNₓ | —Si —SiCl₃, —SiCl₂-alkyl, |
| (oxidized and alloys) | —SiCl(alkyl)₂, —Si(OR)₃, |
| | —Si(OR)₂alkyl and/ |
| | or —SiOR(alkyl)₂ |

NR₂: alkylated/arylated amine
PR₃: arylated phosphide

FIG. 2a illustrates different embodiments of the compound according to the invention. FIG. 2b schematically illustrates how these compounds are connected to a bottom electrode 10 and a top electrode 20.

The bottom electrodes 10 are defined on a silicon substrate on which the silicon CMOS control electronics have already been implemented. This may be effected, for example, by high-resolution photolithography or high-resolution imprint techniques. An advantage consists in the use of silicon (the electrical conductivity of which can be increased by doping in a targeted manner selectively to up to 10⁵ S/cm) as electrode material since silicon is already present as the substrate. Furthermore, silicon can easily be provided with a very thin oxide layer (e.g., thickness of a few angstroms) in a targeted manner, for the covalent binding of the first anchor group 1. For example, the substrate on which the semiconductor components are produced simultaneously serves as an electrode material, thereby obviating the deposition and patterning of a process-critical metal layer.

As an alternative to silicon, it is also possible to use electronegative metals such as aluminum, titanium or copper as material for the bottom electrode 10.

The binding of the first anchor groups 1 to electronegative metals is effected similarly to the binding to an Si/SiO₂ surface. Electronegative metals, in particular aluminum and titanium, are compatible with existing silicon CMOS platforms (in contrast to gold).

In either case, different anchor groups 1, 2 are used at the molecule ends in order to ensure the material selectivity during deposition. The difference results in a selective orientation of the compound to the electrodes 10, 20.

The organic compounds with memory element are optionally deposited from a solution or from the vapor phase (at reduced pressure and elevated temperature).

Independently of the type of deposition, the covalent binding of the compound is effected spontaneously to form an R—Si—O—Si bond. This bond is chemically very stable since the same chemical bond as in quartz, for example, is involved here. The thermal stability of the bond is determined by the organic radical R of the memory molecule, but not by the “anchor binding” itself, so that the thermostability thereof corresponds theoretically to that of quartz. Monolayers that are anchored according to this method are normally stable up to above 200° C.

The quality (orientation, tightness, etc.) of the monolayers comprising the compound is essentially determined by the geometry of the memory unit 3. Thus, dense monolayers can preferably be produced if memory units 3 are used that have a bar-type geometry at the ends of which the anchor groups are bound via linkers 4, 5 (e.g., n-alkane group: n=1 to 18; aryl: phenyl, biphenyl; combinations of the alkanes and aryls). In this case, the operating voltage of the memory cell can be set by way of the length of the linker unit.

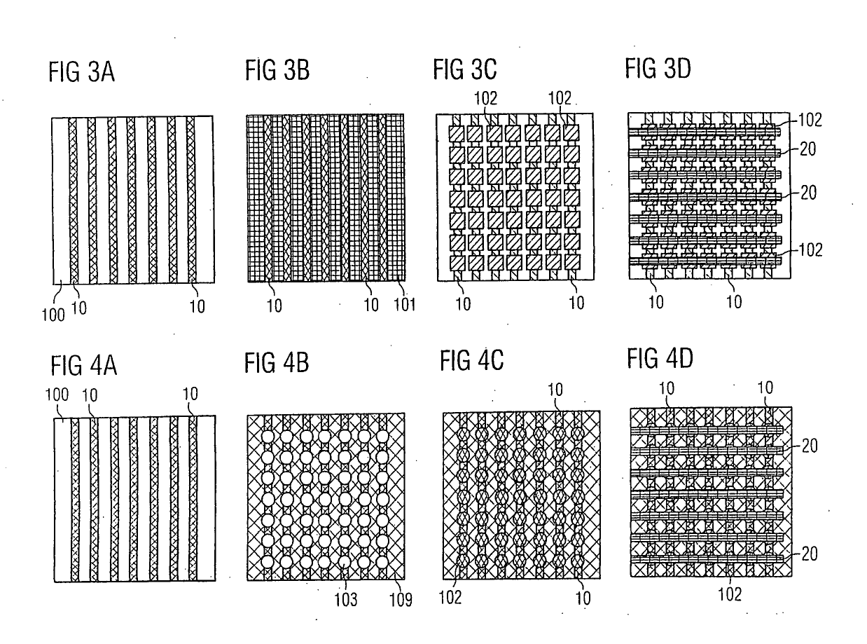

The top electrode 20 may subsequently be applied to the SAM applied in patterned fashion on the bottom electrodes 10. This may be effected by areal deposition of a metal layer and the subsequent patterning thereof (see FIGS. 3a to 3d), or the patterned deposition of metal areas (see FIGS. 4a to 4d).

It is advantageous that the upper metal layer also experiences a binding to the organic memory layer by means of the second anchor group 2. This stabilizes the memory matrix with regard to chemical, thermal and long-term stability.

A memory cell constructed in this way additionally affords the advantage that a rectifier function is obtained due to the asymmetrical construction of the memory cell (two different anchor groups 1, 2). Rectifying cells considerably facilitate the read-out of the stored items of information.

The text below illustrates a way in which compounds, according to embodiments of the invention, can be connected to different electrode materials.

As already explained above, the covalent binding of the compounds and the substrate surface is advantageous. In the case of silicon CMOS platforms, a plurality of chemical possibilities are available for the substrate surface and corresponding first anchor group 1.

Consequently, the covalent binding of the organic memory molecules (R) may be effected via different binding linkages:

a) electrode-Si—O—Si—R

b) electrode-Si—O—R or electrode-Si—CH₂—R

c) electrode-Si—.

In the case of the CMOS-compatible metal electrodes made of aluminum or titanium, the binding to the native or deposited oxide layer is effected in accordance with

d) electrode-AI(Ti)—O—Si—R.

The individual bonds are discussed below, with the specification of the first anchor groups 1, which are suitable for a specific surface type:

a) silicon with native silicon oxide layer or silicon oxide layer produced in a targeted manner—hydroxyl-terminated silicon:

Si—OH: R—SiCl₃; R—SiCl₂-alkyl; R—SiCl(alkyl)₂; R—Si(OR)₃, R—Si(OR)₂alkyl; R—SiOR(alkyl)₂;

b) silicon with hydrogen surface:
Si—H: R—CHO (hv); R—CH=CH₂ (hv);

c) silicon with halogen surface—chloroterminated:
Si—Cl: R—Li; R—MgX (X: halogen);

d) aluminum with native oxide layer or oxide layer produced in a targeted manner—hydroxyl-terminated aluminum or titanium:
AI—OₓOH/TiO,OH: R—SiCl₃; R—SiCl₂-alkyl; R—SiCl(alkyl)₂; R—Si(OR)₃, R—Si(OR)₂alkyl; R—SiOR(alkyl)₂.

Good results may be obtained by variant a) in the production of monolayers on silicon surfaces. In this case, a number of methods are available for producing the required oxide layer (SiO₂), e.g., a thermal oxidation (either in an oxidation furnace or by means of rapid thermal process, RTP) or a short action of oxygen plasma (e.g., 10 sec). Contact with room air (air humidity) already suffices for producing the terminal OH groups (Si—OH).

The organic molecules that exhibit the corresponding functionality can be applied by means of vapor phase deposition or immersion in a suitable solution of the molecules.

A vapor phase deposition is particularly advantageous since dry processes are displacing wet-chemical methods more and more in the semiconductor industry.

The vapor phase deposition is effected in a closed reactor with heating. After being charged with the silicon substrates (wafers), the reactor interior is multiply evacuated and ventilated with inert gas (Ar, N₂) in order to remove residues of oxygen.

Operating pressure and operating temperature are subsequently set; these essentially depend on the radical R (pressure: approximately 10⁻⁶ to 400 mbar; temperature: approximately 80 to 300° C.). The ideal process conditions depend on the volatility (vapor pressure) of the molecules. In this case, the corresponding process window is limited by the thermal stability of the molecular radicals. The coating time during a vapor phase deposition amounts to 30 minutes to 24 hours depending on process conditions.

A deposition from a solution may also be effected as an alternative. In particular, dried, low-polarity, aprotic solvents (e.g., toluene, tetrahydrofuran, cyclohexane) are suitable for preparing the solutions. Concentrations of the solutions in the range of approximately 10⁻⁴ to 1% are particularly suitable for producing dense layers. The deposition is effected by immersing the silicon substrates (wafers) into the prepared solution, subsequent rinsing with the pure process solvent, optional rinsing with a readily volatile solvent (e.g., acetone, dichloromethane) and final drying (furnace, hotplate) under protective gas.

The way in which semiconductor components (here memory devices) are produced using the compounds according to embodiments of the invention is described below.

In principle, the memory cells 102 (see, e.g., FIGS. 3c, 4c) are insulated from one another on a substrate 100 in order to individualize them; that is to say that each memory cell 102 may be driven individually by the driving via the bottom electrode 10 (bit line) and top electrode 20 (word line) (see, e.g., FIGS. 1 and 3d, 4d). The electrodes 10, 20 (crossed lines bottom electrode-top electrode) and also the active memory layer 101 (that is to say the self-assembling monolayer SAM) may be patterned for this purpose.

A first embodiment in this case is the patterning of the memory cells by etching the memory SAM 101, the individual steps being illustrated in FIGS. 3a to 3d.

Firstly, bottom electrodes 10 (e.g., made of silicon, aluminum, titanium, copper) are deposited as bit lines on the square substrate 100 illustrated schematically in FIG. 3a. A self-assembling monolayer 101 with a corresponding embodiment of the compound according to the invention is deposited areally over this as memory SAM (FIG. 3b). In this case, the first anchor group 1 is oriented to the bottom electrode 10.

After application of an etching mask, a subtractive patterning of the memory SAM 101 is performed (FIG. 3c). Finally, the etching mask is removed and a patterning of the top electrodes 20 (word lines) is performed (FIG. 3d). Memory cells 102 produced can thus be driven by bottom electrodes 10 and top electrodes 20.

A second, particularly advantageous embodiment for producing semiconductor components is illustrated in FIGS. 4a to 4d. In contrast to the first embodiment, here the memory SAM 101 is not applied over the whole area. Firstly, however, as in the first embodiment, the substrate 100 is provided with defined bottom electrodes 10 as bit lines (e.g., made of silicon, aluminum, titanium, copper) (FIG. 4a). A passivation layer 109 (approximately 2 to 7 nm thick) is subsequently applied, the passivation layer 109 having contact holes 103 (FIG. 4b). In a next method step, the contact holes 103 are filled with the SAM material using an embodiment of the compound according to the invention (FIG. 4c). The top electrodes 20 are then arranged over this as word lines (FIG. 4d).

In the patterning by means of the contact holes 103, the binding of the SAM is in each case effected in the contact holes 103 on the underlying silicon bottom electrode 10. Accordingly, the passivation layer 109 is not suitable for the covalent binding (targeted binding) of the organic memory molecules.

Passivation layers are, e.g., organic or inorganic layers that do not form a covalent bond with the respective anchor group, having a layer thickness that corresponds approximately to the length of the organic memory molecule.

Both deposition methods (vapor phase deposition, liquid phase deposition) are possible for both embodiments of the patterning methods. The contact hole method (FIGS. 4a to 4d) is particularly advantageous since the memory array is simultaneously mechanically stabilized in this case.

Embodiments of the invention are not restricted to the preferred exemplary embodiments specified above. Rather, a number of variants are conceivable that make use of the compounds according to the invention, the semiconductor components according to the invention and the methods according to the invention also in the case of embodiments of fundamentally different configuration.

What is claimed is:

1. A compound for use in CMOS structures comprising:
at least one molecular memory consisting of an organic linear molecular group;
at least one first anchor group comprising one or both of —CHO and —CH═CH₂ as a reactive group, which is bound after photoinduction to a first electrode of a memory cell with silicon and a hydrogen-containing surface; and
at least one second anchor group comprising a reactive group, which is bound to a second electrode of a memory cell.

2. The compound as claimed in claim 1, wherein the first anchor group and the second anchor group are chemically different.

3. The compound as claimed in claim 1, wherein at least one further first anchor group has a halosilane group and/or an alkoxysilane group.

4. The compound as claimed in claim 3, comprising at least one further of the following reactive groups: —SiCl₃, —SiCl₂-alkyl, —SiCl(alkyl)₂, —Si(OR)₃, —Si(OR)₂alkyl and —SiOR(alkyl)₂, which is bound to the first electrode having silicon and a native silicon oxide layer or silicon oxide layer produced in a targeted manner with a hydroxy-terminated silicon Si—OH.

5. The compound as claimed in claim 3, comprising at least one further of the following reactive groups: —SiCl₃, —SiCl₂-alkyl, —SiCl(alkyl)₂, —Si(OR)₃, —Si(OR)₂alkyl and —SiOR(alkyl)₂, which is bound to the first electrode having titanium or aluminum with a native oxide layer or oxide layer produced in a targeted manner with a hydroxyl-terminated aluminum or titanium.

6. The compound as claimed in claim 1, comprising at least one further of the following reactive groups: —Li and/or —MgX (X: halogen), which is bound to the first electrode having silicon and a halogen-containing surface.

7. The compound as claimed in claim 1, wherein the second anchor group is selected from the group consisting of at least one —SH group, one —SO₂H group or —PR₃ group for binding to the second electrode comprising gold, at least one —NR₂ group or —SH group for binding to the second electrode comprising copper, at least one —NC group for binding to the second electrode comprising platinum, at least one —PO₃H₂ group for binding to the second electrode comprising indium tin oxide (ITO), at least one —COOH group or —CONHOH group for binding to the second electrode comprising Al(AlOₓ), and combinations thereof.

8. The compound as claimed in claim 1, wherein the memory unit has a linear molecular group, a conjugated phenylene-ethynylene oligomer or a compound comprising a bispyridyl group.

9. The compound as claimed in claim 1, wherein at least one of the anchor groups is connected to a molecular memory unit via a linker.

10. The compound as claimed in claim 9, wherein at least one linker is an n-alkane or an aryl.

11. The compound as claimed in claim 9, wherein linkers connected to the first and second anchor groups are formed differently, in particular have different lengths.

12. A semiconductor component having memory cells comprising:
at least one first electrode;
at least one second electrode; and
at least one self-assembling monolayer comprising a compound having at least one molecular memory consisting of an organic linear molecular group and at least one first anchor group comprising one or both of —CHO and —CH═CH₂ as a reactive group, the self-assembling monolayer being arranged between the at least one first electrode and the at least one second electrode.

13. The semiconductor component as claimed in claim 12, wherein the at least one first electrode, is a bottom electrode, and comprises at least one of silicon, titanium, aluminum, titanium or copper.

14. The semiconductor component as claimed in claim 12, wherein the at least one second electrode is a top electrode, and comprises aluminum, titanium, gold, copper, platinum, ITO, TaNₓ, TiNₓ, WNₓ (oxidized and alloys) or Al(AlOₓ).

15. A method for producing a semiconductor component, the method comprising:
forming at least one first electrode for driving at least one memory cell on a substrate;
forming on the first electrode a sheetlike self-assembling monolayer comprising a compound for use as at least one memory cell; and
forming at least one second electrode on the monolayer connected to at least one memory cell.

16. The method as claimed in claim 15, wherein the vapor phase deposition is effected at a pressure of 10⁻⁶ to 400 mbar, a temperature of 80 to 300° C., or under a protective gas atmosphere.

17. The method as claimed in claim 15, wherein the liquid phase deposition is effected from a slightly polar, aprotic solvent, having a concentration of molecules to be deposited of 10⁻⁴ to 1%.

18. The method as claimed in claim 15, further comprising:
forming an etching mask on the monolayer before the forming of the second electrode;
performing a subtractive patterning of the monolayer using the etching mask; and
removing the etching mask from the substrate before the forming of the second electrode.

19. The method as claimed in claim 15, further comprising:
forming a passivation layer on the at least one first electrode;
forming at least one hole in the passivation layer over the at least one first electrode; and
forming the monolayer at least in the at least one hole in the passivation layer.

20. The method as claimed in claim 15, further comprising forming an oxide layer on the substrate by thermal oxidation.
